(19) United States
(12) Patent Application Publication
(10) Pub. No.: US 2012/0314409 A1
(43) Pub. Date: Dec. 13, 2012

(54) OPTICAL SEMICONDUCTOR-BASED TUBE TYPE LIGHTING APPARATUS

(75) Inventors: Kyung Rye KIM, Seongnam-si (KR); Jae Young CHOI, Seongnam-si (KR); Kyoung Onn KIM, Seongnam-si (KR)

(73) Assignee: POSCO LED COMPANY LTD., Seongnam-si (KR)

(21) Appl. No.: 13/590,943

(22) Filed: Aug. 21, 2012

Related U.S. Application Data
(62) Division of application No. 13/296,122, filed on Nov. 14, 2011.

(30) Foreign Application Priority Data
May 23, 2011 (KR) 10-2011-0048652
Aug. 8, 2011 (KR) 10-2011-0078701

(51) Int. Cl. F21V 29/00; H01L 21/00

(52) U.S. Cl. 362/218; 29/25.01

(57) ABSTRACT

Embodiments of the invention provide an optical semiconductor-based tube type lighting apparatus capable of enlarging light distribution to have improved assembly characteristics. The lighting apparatus includes an elongated light-transmitting tube; a linear slit formed on the light-transmitting tube in a longitudinal direction thereof; and at least one bar-shaped optical semiconductor module secured to the light-transmitting tube, with edges of the slit fitted into side surfaces of the bar-shaped optical semiconductor module. Here, the optical semiconductor module includes a heat sink, a PCB attached to the heat sink, and an array of semiconductor optical devices arranged on the PCB. The heat sink is partially exposed from the light-transmitting tube through the slit.

### CROSS-REFERENCE TO RELATED APPLICATIONS

This application is a divisional of U.S. patent application Ser. No. 13/296,122, filed on Nov. 14, 2011, and claims priority from and the benefit of Korean Patent Application No. 10-2011-0048652, filed on May 23, 2011, and No. 10-2011-0078701, filed on Aug. 8, 2011, all of which are hereby incorporated by reference for all purposes as if fully set forth herein.

### BACKGROUND OF THE INVENTION

1. Field of the Invention

The present invention relates to optical semiconductor-based tube type lighting apparatuses.

2. Discussion of the Background

Generally, fluorescent lamps and incandescent lamps are used as a light source for lighting. Incandescent lamps have low economic feasibility due to high power consumption and thus demand for incandescent lamps continues to decrease. Further, it is predicted that this trend will continue into the future. On the contrary, fluorescent lamps have higher economic feasibility due to low power consumption, which is about ⅓ that of incandescent lamps. However, fluorescent lamps require application of high voltage, causing a blackening phenomenon and shortening the lifespan thereof. Further, mercury injected together with argon gas into a vacuum glass tube of a fluorescent lamp is toxic and environmentally unfriendly.

Recently, demand for LED lighting apparatuses employing an LED as a light source has rapidly increased. The LED lighting apparatus has long lifespan and requires low power for operation. Further, the LED lighting apparatus does not use a toxic substance such as mercury, thereby guaranteeing environmental friendliness.

Various kinds of LED lighting apparatuses having various structures have been developed. For example, a fluorescent lamp type or tube type LED lighting apparatus has a similar configuration to that of a fluorescent lamp.

FIG. 1 is a cross-sectional view of a conventional tube type LED lighting apparatus.

Referring to FIG. 1, the conventional tube type LED lighting apparatus includes an elongated light-transmitting cover 2 having a substantially semi-circular cross-section and open at an upper side thereof, and an elongated LED module 4 coupled to the open upper side of the light-transmitting cover. The LED module 4 includes an elongated heat sink 4a having a substantially semi-circular cross-section, a long printed circuit board (PCB) 4b attached to a flat surface of the heat sink 4a, and LEDs 4c arranged on the PCB 4b in a longitudinal direction. The LEDs 4c inside the LED module 4 emit light to the front of the lighting apparatus, that is, in a downward direction.

The conventional LED lighting apparatus emits light through an arcuate area in a predetermined angle range (in the range of about 120-150 degrees) at a lower portion of the light-transmitting plastic cover 2. Further, since the back of the conventional tube type LED lighting apparatus is completely blocked by the heat sink 4a, light is not distributed to rear and lateral sides of the light-transmitting cover 2.

Such a conventional tube type LED lighting apparatus has very unsatisfactory light distribution characteristics as compared with existing fluorescent lamps. Accordingly, when the conventional tube type LED lighting apparatus is used in homes or offices instead of the existing fluorescent lamps, dark areas are generated at the rear and lateral sides of the lighting apparatus. Such dark areas cause user dissatisfaction as light coverage is uneven.

Such a conventional tube type LED lighting apparatus is configured to allow light to be diffusively emitted only through the semi-circular light-transmitting cover 2 and thus has lower light distribution characteristics than existing fluorescent lamps, which employ a light-transmitting tube. In addition, in the conventional tube type LED lighting apparatus, the LED 4c or the LED module including the LED 4c is located at the center of a tube-shaped cross-section defined by an outer periphery of the light-transmitting cover 2 and an outer periphery of the heat sink, thereby causing a short distance between a light emitting plane of the LED 4c and the light-transmitting cover 2 on a predetermined cross-sectional area of the tube type LED lighting apparatus. Since an area of the light-transmitting cover 2 through which light from the LED 4c passes decreases with decreasing distance between the light emitting plane of the LED 4c and the light-transmitting cover 2, the conventional tube type LED lighting apparatus has unsatisfactory light distribution characteristics towards the lateral and rear sides thereof.

### SUMMARY OF THE INVENTION

An exemplary embodiment of the invention provides a tube type optical semiconductor-based lighting apparatus which includes a bar-shaped optical semiconductor module directly mounted on a wall of a light-transmitting tube to increase a distance between a semiconductor optical device and the light-transmitting tube in order to improve light distribution.

Other exemplary embodiments of the invention provide an optical semiconductor-based lighting apparatus and a method of manufacturing the same, which has improved assembling properties when directly mounting a bar-shaped optical semiconductor module to a wall of a light-transmitting tube such that the optical semiconductor module is partially exposed from the light-transmitting tube.

Additional features of the invention will be set forth in the description which follows, and in part will be apparent from the description, or may be learned by practice of the invention.

An exemplary embodiment of the invention provides an optical semiconductor-based tube type lighting apparatus, which includes an elongated light-transmitting tube; a linear slit formed on the light-transmitting tube in a longitudinal direction thereof; and at least one bar-shaped optical semiconductor module secured to the light-transmitting tube, with edges of the slit fitted into side surfaces of the bar-shaped optical semiconductor module in a widened state and the side surfaces of the optical semiconductor module being subjected to elastic force from the light-transmitting tube in a direction of narrowing the slit. Here, the optical semiconductor module includes a heat sink, a PCB attached to the heat sink, and an array of semiconductor optical devices arranged on the PCB. The heat sink is partially exposed from the light-transmitting tube through the slit.

The light-transmitting tube may include a pair of hooks formed on an inner periphery thereof in the longitudinal direction of the light transmitting tube to face each other, the slit may be formed in a middle between the pair of hooks in the longitudinal direction of the light transmitting tube, and right and left protrusions of the optical semiconductor module may be respectively inserted into the pair of hooks in a sliding manner when the slit is widened by external force.

When the slit is widened by external force, a heat dissipation protrusion at a rear side of the heat sink may be inserted into the slit in a sliding manner and exposed from the light-transmitting tube.

The heat sink may be provided with right and left guide wings, and the right and left guide wings and right and left edges of the PCB may be inserted into the corresponding hooks to form the right and left protrusions of the optical semiconductor module, respectively.

The PCB may be a metal-based MCPCB or MPCB.

In the light-transmitting tube, each of the optical semiconductor modules may be disposed so as not to face another optical semiconductor module at an opposite side thereof.

A further exemplary embodiment of the invention provides a method of manufacturing a semiconductor-based tube type lighting apparatus, which includes: preparing an elongated light-transmitting tube; forming a linear slit on the light-transmitting tube in a longitudinal direction of the light-transmitting tube; and assembling at least one optical semiconductor module to the light-transmitting tube by widening the slit and inserting the at least one optical semiconductor module into the widened slit in a sliding manner.

The light-transmitting tube may include a pair of hooks formed on an inner periphery of the light-transmitting tube to face each other in a longitudinal direction.

The assembling at least one optical semiconductor module may include inserting right and left protrusions formed at opposite sides of the optical semiconductor module into the respective hooks in a sliding manner, and inserting a protrusion formed at a rear side of the optical semiconductor module into the widened slit in a sliding manner to be exposed from the light-transmitting tube.

The forming a linear slit may include forming the slit over the entire length of the light-transmitting tube, and the assembling at least one optical semiconductor module may include widening the slit over the entire length of the light-transmitting tube and inserting the optical semiconductor module into the slit.

The forming a linear slit may include forming the slit on the light emitting tube except for a portion near one end of the light-transmitting tube, and the assembling at least one optical semiconductor module may include widening the slit only in a partial length region of the light-transmitting tube and inserting the optical semiconductor module into the widened slit. Here, the method may further include removing the portion of the light-transmitting tube where the slit is not formed, after assembling the at least one optical semiconductor module.

Herein, the term “semiconductor optical device” refers to a device including or using an optical semiconductor such as a light emitting diode chip. Advantageously, the semiconductor optical device is an LED package including a light emitting diode chip therein.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view of an LED lighting apparatus, which is a conventional semiconductor-based lighting apparatus.

FIG. 2 is a perspective view of an optical semiconductor-based tube type lighting apparatus in accordance with one exemplary embodiment of the invention.

FIG. 3 is a cross-sectional view taken along line I-I of FIG. 2.

FIG. 4 is a cross-sectional view of an optical semiconductor-based tube type lighting apparatuses in accordance with another exemplary embodiment of the invention.

FIG. 5 is a cross-sectional view of an optical semiconductor-based tube type lighting apparatuses in accordance with a further exemplary embodiment of the invention.

FIG. 6 is a perspective view of an optical semiconductor-based tube type lighting apparatuses in accordance with yet another exemplary embodiment of the invention.

FIG. 7 is an exploded perspective view of the optical semiconductor-based tube type lighting apparatuses of FIG. 6.

FIG. 8a is a partially enlarged perspective view of the semiconductor-based tube type lighting apparatus of FIG. 6.

FIG. 8b is a partially enlarged perspective view of the semiconductor-based tube type lighting apparatus of FIG. 6.

FIG. 9 is a cross-sectional view of the optical semiconductor-based tube type lighting apparatus of FIG. 6.

FIG. 10 is a perspective view of an optical semiconductor-based tube type lighting apparatuses in accordance with yet another exemplary embodiment of the invention.

FIG. 11 is a perspective view of the optical semiconductor-based tube type lighting apparatuses of FIG. 10.

FIG. 12 is a perspective view of an optical semiconductor-based tube type lighting apparatuses in accordance with yet another exemplary embodiment of the invention.

FIG. 13 is a perspective view of the optical semiconductor-based tube type lighting apparatuses of FIG. 12.

FIG. 14 is a perspective view of the optical semiconductor-based tube type lighting apparatus of FIG. 12.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the embodiments set forth herein. Rather, these exemplary embodiments are provided so that this disclosure is thorough, and will fully convey the scope of the invention to those skilled in the art. In the drawings, the sizes and relative sizes of layers and regions may be exaggerated for clarity. Like elements will be denoted by like reference numerals and repeated descriptions thereof will be omitted herein.

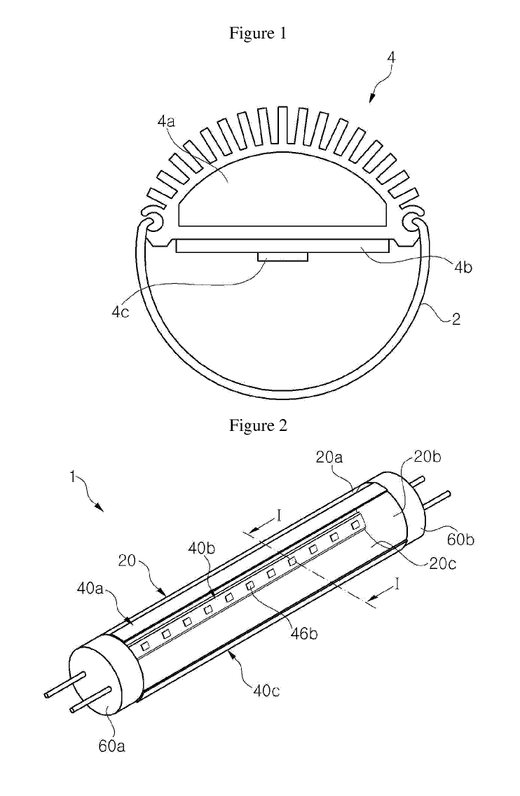

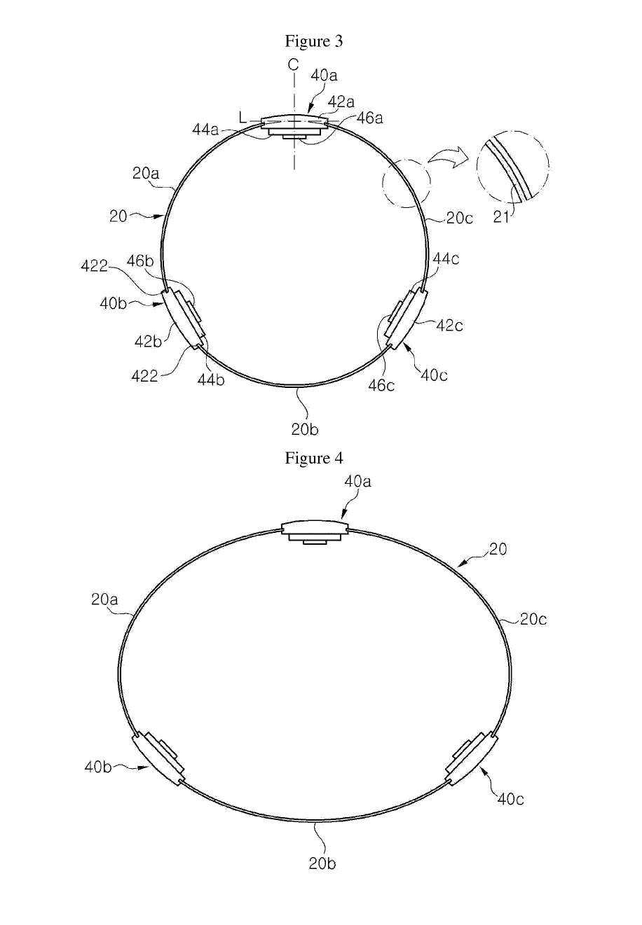

FIG. 2 is a perspective view of an optical semiconductor-based tube type lighting apparatus in accordance with one exemplary embodiment of the invention, and FIG. 3 is a cross-sectional view taken along line I-I of FIG. 2.

Referring to FIG. 2 and FIG. 3, the optical semiconductor-based tube type lighting apparatus 1 according to the exemplary embodiment of the invention is similar to a fluorescent lamp. The optical semiconductor-based tube type lighting apparatus 1 includes an elongated hollow light-transmitting tube 20 having a circular cross-section, and three optical semiconductor modules 40a, 40b, 40c arranged along a circumference of the light-transmitting tube 20.

In this embodiment, the light-transmitting tube 20 includes three elongated slit pieces 20a, 20b, 20c. Each of the slit pieces 20a, 20b, 20c is made of a light-transmitting plastic material exhibiting good impact resistance. Further, all of the slit pieces 20a, 20b, 20c have the same arcuate cross-section. When the three slit pieces 20a, 20b, 20c are arranged to form a circular cross-section, three elongated mounting gaps are formed between the slit pieces 20a, 20b, 20c.

The three bar-shaped optical semiconductor modules 40a, 40b, 40c are mounted to the three mounting gaps, respectively. As a result, the three optical semiconductor module 40a, 40b, 40c are placed at equal intervals of about 120 degrees along the circular circumference of the light-transmitting tube 20. Accordingly, the three optical semiconductor modules 40a, 40b, 40c are placed at three vertices of an imaginary equilateral triangle.

The light-transmitting tube 20 is provided at opposite sides thereof with two connectors 60a, 60b. Both of the connectors 60a, 60b may serve as electrical connectors for supplying power to the optical semiconductor modules 40a, 40b, 40c. Alternatively, only one of the connectors 60a, 60b, for example, a connector 60a, may serve as an electrical connector for supplying power to the optical semiconductor modules 40a, 40b, 40c. In this case, the other connector 60b may serve only as a mechanical connector for connecting one end of the light-transmitting tube 20 to one end of the connector. Furthermore, both of the connectors 60a, 60b may serve as mechanical connectors instead of electrical connectors. In this case, a separate electrical connector, which does not provide a function of a mechanical connector, may be provided to the light-transmitting tube 20 through an opening of the light-transmitting tube 20 together with a cable.

Herein, the connector which does not provide a function of an electrical connector and serves only as a mechanical connector will be defined as a “dummy connector”.

The three optical semiconductor modules 40a, 40b, 40c may be mounted at an equal mounting angle on the light-transmitting tube 20. The mounting angle is defined as an angle between a tangential line L on the light-transmitting tube 20 at a mounting position of the corresponding optical semiconductor module and a central axis line C of light emitted from the corresponding optical semiconductor module. In this embodiment, the mounting angle is 90 degrees. In this embodiment, since the light-transmitting tube 20 has an arcuate or curved surface at the mounting position of the optical semiconductor module 40a, 40b or 40c, the angle between the tangential line L and the central axis line C is defined as the mounting angle. However, in the case where the light-transmitting tube has a linear surface at the mounting position of the optical semiconductor module, an angle between the linear surface and the central axis line of light emitted from the optical semiconductor module may be defined as the mounting angle. When the mounting angles of the optical semiconductor modules differ, design conditions are complicated, thereby making difficult to obtain a desired lighting apparatus with desired light distribution characteristics. Further, when the mounting angles differ, there is a possibility of light distribution being biased towards one side in a bisymmetrical light-transmitting tube 20. Therefore, the optical semiconductor modules 40a, 40b, 40c may be secured at an equal mounting angle to the light-transmitting tube 20 under different conditions in order to achieve desired light distribution.

As clearly shown in FIG. 3, each of the optical semiconductor modules 40a, 40b or 40c includes an elongated bar-shaped metal base 42a, 42b or 42c including a heat sink or acting as a heat sink, a PCB 44a, 44b or 44c mounted on the base 42a, 42b or 42c, and at least one array of semiconductor optical devices 46a, 46b or 46c mounted on the PCB 44a, 44b or 44c. On the PCB 44a, 44b or 44c, the semiconductor optical devices are arranged in at least one row to constitute the at least one array of semiconductor optical devices. The semiconductor optical devices 46a, 46b or 46c may be LED packages including a light emitting diode chip received therein, and may further include a wavelength converting material, which converts light emitted from the light emitting diode chip. However, the semiconductor optical device may be another optical semiconductor chip or device including or using the optical semiconductor chip, instead of the light emitting diode chip. Each of the metal bases 42a, 42b or 42c is partially exposed from the light-transmitting tube 20 through the mounting gap described above.

Each of the bases 42a, 42b or 42c of the optical semiconductor module 40a, 40b or 40c may be used to connect two adjacent slit pieces (20a and 20b; 20 and 20c; or 20c and 20a) to each other. In this embodiment, each of the bases 42a, 42b or 42c is formed at opposite sides thereof with connection grooves 422 each corresponding to a slit edge of the slit piece 20a, 20b or 20c, and the edges of the slit piece 20a, 20b or 20c, that is, opposite edges of the corresponding slit (or, cut surfaces), are fitted into side surfaces of the optical semiconductor module 40a, 40b or 40c, particularly, into the connection grooves 422, so that the slit pieces 20a, 20b, 20c are assembled to the optical semiconductor modules 40a, 40b, 40c.

Among the three optical semiconductor modules 40a, 40b, 40c, a first optical semiconductor module 40a is placed at an upper portion of the circumference of the light-transmitting tube 20 and emits light downwards. Assuming that the optical semiconductor-based tube type lighting apparatus 1 according to this embodiment is horizontally mounted on the ceiling, the semiconductor optical devices 46a of the first optical semiconductor module 40a are placed near the uppermost end of the circumference of the light-transmitting tube 20 and act as light sources for illuminating an indoor space beneath the lighting apparatus. Herein, the uppermost end of the circumference refers to a position nearest to the ceiling.

Since the optical semiconductor modules 40a, 40b, 40c are arranged at equal intervals of 120 degrees, the first optical semiconductor module 40a does not face any other optical semiconductor module at an opposite side thereof. Although the semiconductor optical devices 46a of the first optical semiconductor module 40a emit light at an orientation angle in the range of about 120 to 150 degrees, a region directly beneath the first optical semiconductor module 40a has a higher light distribution amount than other regions, and thus there is substantially no light loss due to interference with light from the other optical semiconductor modules 40b, 40c.

Among the three optical semiconductor modules 40a, 40b, 40c, second and third optical semiconductor modules 40b, 40c are placed at opposite sides of a lower portion of the circumference of the light-transmitting tube 20 and emit light towards upper sides opposite thereto. Light emitted from the optical semiconductor devices 46b, 46c of the second and third optical semiconductor modules 40b, 40c covers regions that are not covered by light emitted from the first optical semiconductor module 40a, that is, rear and lateral regions of the lighting apparatus.

As the optical semiconductor modules 40a, 40b, 40c are arranged at constant intervals of 120 degrees, the second optical semiconductor module 40b does not face any other optical semiconductor module at an opposite side thereof, and the third optical semiconductor module 40c does not face any other optical semiconductor module at an opposite side thereof. Thus, light emitted from the semiconductor optical devices 46b, 46c of the second and third optical semiconductor modules 40b, 40c may illuminate the upper portion (or the rear side) of the lighting apparatus without substantially interfering with light from the other optical semiconductor modules. When the lighting apparatus is mounted on the ceiling, the second and third optical semiconductor modules 40b, 40c illuminate regions near the ceiling.

As such, the first, second and third optical semiconductor modules 40a, 40b, 40c are arranged at equal intervals along the circumference of the light-transmitting tube 20, so that light is uniformly distributed throughout the overall region of the light-transmitting tube 20, that is, over a region of 360 degrees, thereby providing uniform light distribution characteristics. Advantageously, power applied to the second and third optical semiconductor modules 40b, 40c may be lower than power applied to the first optical semiconductor module 40a to provide a lower light output at the rear side of the light-transmitting tube. To this end, the second and third optical semiconductor modules 40b, 40c may employ semiconductor optical devices having lower power consumption or may include a smaller number of semiconductor optical devices than the first optical semiconductor module. Here, application power and light output of the second optical semiconductor module 40b may be the same as those of the third optical semiconductor module 40c.

The semiconductor optical devices 46a of the first optical semiconductor module 40a may be configured to emit light having a desired color temperature, for example, about 5000K, and the second and third optical semiconductor modules 40b, 40c may include at least one semiconductor optical device 46b or 46c, which emits light having a different color temperature from that of the light emitted from the semiconductor optical device 46a of the first optical semiconductor module 40a, so that the lighting apparatus may act as a light source in the form of an indirect lamp having a color dimming function.

The optical semiconductor-based tube type lighting apparatus 1 according to this embodiment includes a light spreading layer 21 formed on an inner periphery of the light-transmitting tube 20. The light-transmitting tube 20 may be formed by coating a light spreading material on the inner periphery of the light-transmitting tube 20 or attaching a light spreading sheet thereto. The light spreading layer 21 widely spreads light passing through the light-transmitting tube 20, thereby preventing a surrounding region of the optical semiconductor modules 40a, 40b, 40c from becoming relatively dark. Alternatively, the light spreading layer may be formed on the outer periphery of the light-transmitting tube 20, or a light spreading material may be contained in a light-transmitting plastic material constituting the light-transmitting tube 20. Further, the light-transmitting tube 20 may include a wavelength converting material, preferably, remote phosphors. The remote phosphors may be formed on the inner periphery and/or outer periphery of the light-transmitting tube 20, and may be contained in a resin for the light-transmitting tube 20.

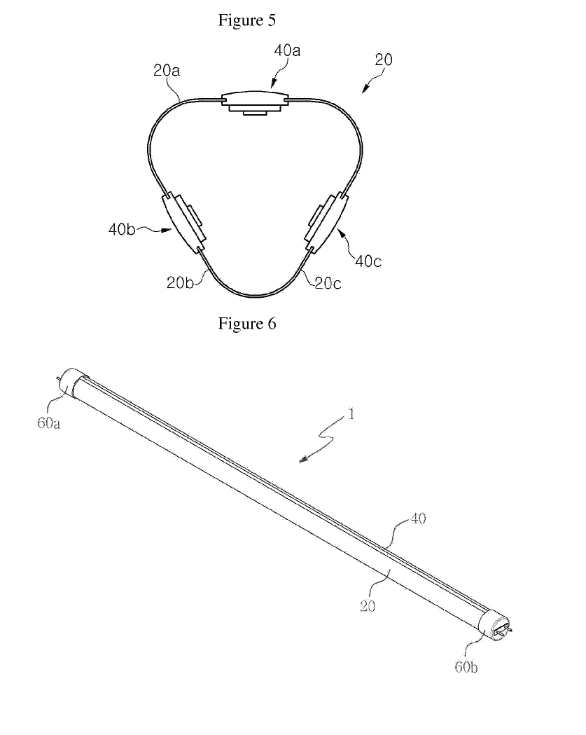

FIG. 4 and FIG. 5 illustrates various exemplary embodiments of the invention.

In the optical semiconductor-based tube type lighting apparatus of FIG. 4, three optical semiconductor modules, that is, a first optical semiconductor module 40a, a second optical semiconductor module 40b and a third optical semiconductor module 40c, are arranged at intervals of about 120 degrees along the circumference of a substantially oval light-transmitting tube 20. The first, second and third optical semiconductor modules 40a, 40b, 40c are placed at three vertices of an isosceles triangle. As in the embodiment described above, the first optical semiconductor module 40a illuminates a region beneath the lighting apparatus, that is, a lower indoor space, and the second and third optical semiconductor modules 40b, 40c illuminate a region above the lighting apparatus, that is, a rear region near the ceiling.

In the optical semiconductor-based tube type lighting apparatus of FIG. 5, three optical semiconductor modules, that is, a first optical semiconductor module 40a, a second optical semiconductor module 40b and a third optical semiconductor module 40c, are arranged at intervals of about 120 degrees along the circumference of a light-transmitting tube 20 having a cross-section of a substantially equilateral triangle, which has a rounded surface near each vertex. The first optical semiconductor module 40a is placed on a horizontal upper side of the light-transmitting tube 20, and the second and third optical semiconductor modules 40b, 40c are placed on the remaining two side surfaces of the light-transmitting tube 20 in a cross-sectional view. The first optical semiconductor module 40a illuminates a region beneath the lighting apparatus, that is, a lower indoor space, and the second and third optical semiconductor modules 40b, 40c illuminate a region above the lighting apparatus, that is, a rear region near the ceiling. When a vertex or a sharp tip is present at a portion requiring much distribution of light, light loss can occur at such a portion. Thus, such a portion may have a rounded surface to prevent light loss as described above. As such, the light-transmitting tube 20 may be formed to exclude a vertex, sharp tip or other sharp shapes at a portion requiring much distribution of light.

Next, a tube type optical semiconductor-based lighting apparatus according to another exemplary embodiment of the invention and a method of manufacturing the same will be described. In the description of the embodiment, repeated description of like components will be omitted.

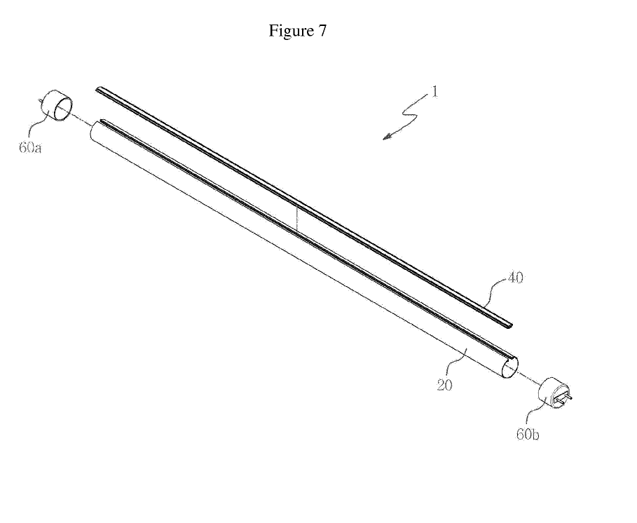

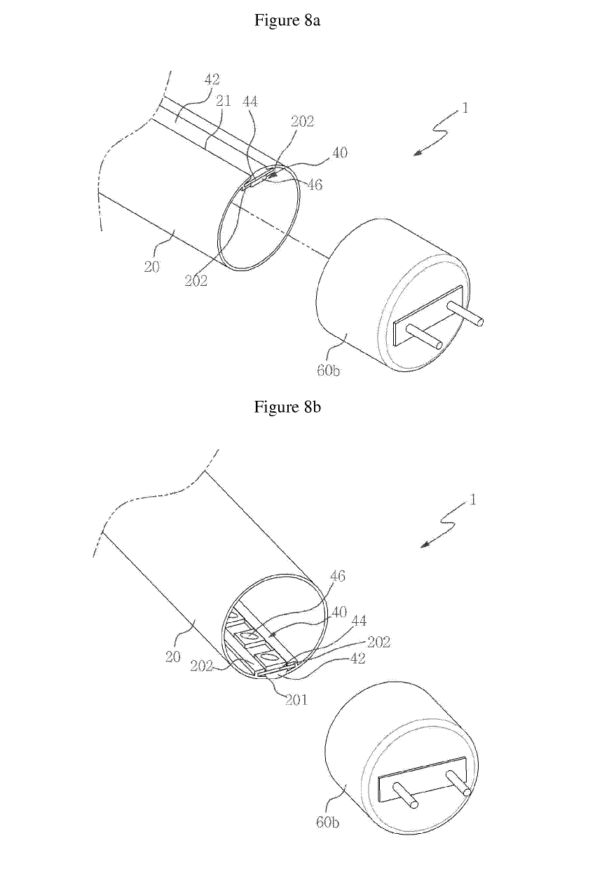

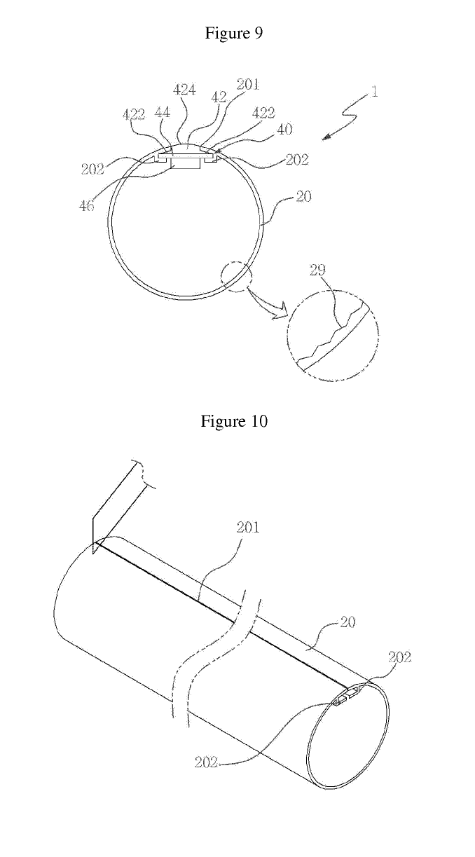

FIG. 6 is a perspective view of an optical semiconductor-based tube type lighting apparatus according to another exemplary embodiment of the invention, FIG. 7 is an exploded perspective view of the optical semiconductor-based tube type lighting apparatus of FIG. 6, FIGS. 8a and 8b are partially enlarged perspective views of the semiconductor-based tube type lighting apparatus according to the exemplary embodiment, from which a connector is separated, and FIG. 9 is a cross-sectional view of the optical semiconductor-based tube type lighting apparatus according to the exemplary embodiment. In the description of this exemplary embodiment, the same or like components to those of the above embodiment will be indicated by the same reference numerals as those of the above embodiment.

As shown in FIG. 6 to FIG. 9, the optical semiconductor-based tube type lighting apparatus 1 according to this embodiment includes an elongated hollow plastic light-transmitting tube 20 having a substantially circular cross-section, and a bar-shaped semiconductor module 40 disposed in a longitudinal direction of the light-transmitting tube 20.

In this embodiment, the light-transmitting tube 20 has an elongated mounting gap formed in the longitudinal direction thereof. The circumference of the light-transmitting tube is continuously formed except for the mounting gap. The substantially bar-shaped optical semiconductor module 40 is fitted into the mounting groove and is thus secured to a circular wall of the light-transmitting tube 20. Except for the region where the optical semiconductor module 40 is mounted, no optical semiconductor module 40 is present on the overall wall of the light-transmitting tube 20.

The light-transmitting tube 20 is provided at opposite ends thereof with two connectors 60a, 60b. Both of the connectors 60a, 60b serve as electrical connectors for supplying power to the optical semiconductor module 40. Alternatively, only one of the connectors 60a, 60b, for example, a connector 60a, may serve as an electrical connector for supplying power to the optical semiconductor module 40. In this case, the other connector 60b may serve only as a mechanical connector for connecting one end of the light-transmitting tube 20 to one end of the connector. Furthermore, both of the connectors 60a, 60b may serve as mechanical connectors instead of electrical connectors. In this case, a separate electrical connector, which does not provide a function of a mechanical connector, may be provided to the light-transmitting tube 20 through an opening of the light-transmitting tube 20 together with a cable.

As clearly shown in FIG. 8b and FIG. 9, the optical semiconductor module 40 includes an elongated heat sink 42, a PCB 44 attached to a flat front side of the heat sink 42, and an array of semiconductor optical devices 46 mounted on the PCB 44. The semiconductor optical devices mounted on the PCB 44 are longitudinally arranged in a single row to constitute an array of semiconductor optical devices. Here, the PCB 44 may be a metal-based MCPCB (Metal Core Printed Circuit Board) or MPCB (Metal Printed Circuit Board) having high thermal conductivity. The heat sink 42 is partially exposed from the light-transmitting tube 20 through the mounting gap.

As described in detail below, the optical semiconductor module 40 is longitudinally inserted into the mounting gap of the light-transmitting tube 20 in a sliding manner and is firmly coupled to the light-transmitting tube 20.

The light-transmitting tube 20 include a guide structure which allows sliding insertion of the optical semiconductor module 40 into the light-transmitting tube 20 along the mounting gap, and the heat sink 42 and the PCB 44 of the optical semiconductor module 40 have shapes to be slid into the light-transmitting tube 20 through the guide structure in a state of being coupled to each other.

The mounting gap and the guide structure of the light-transmitting tube 20 will be described in more detail hereinafter.

The light-transmitting tube 20 includes a linear slit 201 longitudinally formed to provide the mounting gap. As described in detail hereinafter, the slit 201 may be formed by longitudinally cutting the light-transmitting tube 20 with a laser or a sharp cutter such as a knife. The light-transmitting tube 20 is formed with a single guide structure, which includes a pair of hooks 202 facing each other and formed near the slit 201 on the inner periphery of the light-transmitting tube 20 in the longitudinal direction thereof, such that the optical semiconductor module 40 is guided by the hooks 202 in a sliding manner.

As described below, the hooks 202 may be integrally formed with the light-transmitting tube 20 when forming the light-transmitting tube 20. Further, the slit 201 is formed by longitudinally cutting the light-transmitting tube 20 having the hooks 202. Here, since the slit 201 is placed between the pair of hooks 202, the pair of hooks 202 may be widened by forcibly widening the slit 201.

As clearly shown in FIG. 9, the heat sink 42 has the flat front surface to which the PCB 44 is attached. Further, the heat sink 42 includes a pair of guide wings 422 formed at the right and left of a rear side thereof, and a heat dissipation protrusion 424 at the center of the rear side. Each of the guide wings 422 has a flat front surface and a curved rear surface, which is identical or similar to the inner periphery of the light-transmitting tube 20. The heat dissipation protrusion 424 extends along the center of the rear side of the heat sink 42 in the longitudinal direction and has vertical surfaces at opposite sides thereof. The heat dissipation protrusion 424 has a curved rear surface, which is identical or similar to the outer periphery of the light-transmitting tube 20.

The PCB 44 has right and left edges with respect to the center thereof on which the semiconductor optical devices 46 are arranged. The right and left edges of the PCB 44 protrude together with the guide wings 422 of the heat sink 42 from opposite sides of the optical semiconductor module 40. The PCB 44 may have a greater width than the front side of the heat sink 42, so that right and left edges of the PCB 44 are located farthest from the right and left of the optical semiconductor module 40.

When the optical semiconductor module 40 is fitted into the mounting gap of the light-transmitting tube 20 in a sliding manner, the left guide wing 422 of the heat sink 42 and the left edge of the PCB 44 are inserted together into the left hook 202, and the right guide wing 422 of the heat sink 42 and the right edge of the PCB 44 are inserted together into the right hook 202 in the longitudinal direction. That is, each of the hooks 202 holds the edges of the heat sink 42 and the PCB 44 at the same time. In addition, since the pair of hooks 202 has the guide structure, the optical semiconductor module 40 may be inserted into the pair of hooks 202 in a sliding manner.

Since the insertion of the optical semiconductor module 40 in the longitudinal direction is carried out after forcibly widening the slit 201 of the light-transmitting tube 20, the slit 210 is elastically deformed to be narrowed after insertion of the optical semiconductor module 40, so that the optical semiconductor module 40 may be firmly secured to the mounting gap.

When the portions of the optical semiconductor module 40 inserted into the respective hooks 202 are respectively referred to as left and right protrusions of the optical semiconductor module 40, each of the left and right protrusions includes the guide wing 422 of the heat sink 42 and the edge of the PCB 44 on the guide wing. A rear protrusion of the optical semiconductor module 20, that is, the heat dissipation protrusion 424 at the rear side of the heat sink 42, is exposed from the light-transmitting tube 20 through the widened slit 201 of the light-transmitting tube 20. Right and left edges of the slit 201, that is, right and left cut surfaces, are inserted into the side surfaces of the optical semiconductor module to contact side surfaces of the heat dissipation protrusion 424. At this time, the edges of the slit 201, that is, the cut surfaces, forcibly compress both sides of the protrusion 424 by elasticity narrowing the slit 201.

As clearly shown in FIG. 9, an undulating light spreading pattern 29 for spreading light is formed on the inner periphery of the light-transmitting tube 20. The light spreading pattern 29 may be formed on the inner periphery of the light-transmitting tube 20 when forming the light-transmitting tube 20 by, for example, injection molding.

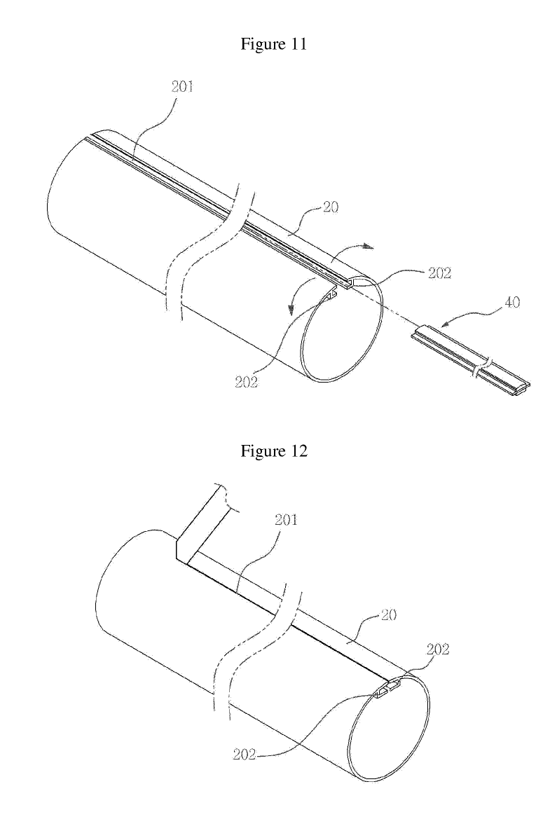

Next, a method of manufacturing the optical semiconductor-based tube type lighting apparatus as described above according to one exemplary embodiment will be described with reference to FIG. 10 and FIG. 11.

Referring to FIG. 10, a light-transmitting tube 20 is prepared by, for example, injection molding. Here, the light-transmitting tube 20 has a pair of hooks 202 elongated in the longitudinal direction of the light-transmitting tube 20 and facing each other. Then, an elongated linear slit 201 is formed over the entire length of the light-transmitting tube 20 at the middle between the pair of hooks 202. The slit 201 is formed by longitudinally cutting the light-transmitting tube 20 with a laser or a sharp cutter such as a knife. As the slit 201 is formed, the light-transmitting tube 20 is formed with a mounting gap, which is placed between the pair of hooks 202 and is capable of being widened by external force.

Then, referring to FIG. 11, the width of slit 201 is widened by applying force to the light-transmitting tube 20 in a direction of an arrow. Next, the linear optical semiconductor module 40 is inserted in a sliding manner into the mounting gap formed by widening the slit 201. At this time, right and left protrusions of the linear optical semiconductor module 40 are respectively inserted into and guided by the pair of hooks 202, and a rear protrusion of the optical semiconductor module 40 is inserted into and guided by the widened slit 201 in a sliding manner. As described above, each of the protrusions of the optical semiconductor module 40 respectively inserted into the pair of hooks 202 includes the right or left edge of the PCB and the right or left guide wing of the heat sink.

Then, one end or both ends of the light-transmitting tube 20 are finished with a connector, thereby completing the optical semiconductor-based tube type lighting apparatus.

Next, a method of manufacturing the optical semiconductor-based tube type lighting apparatus as described above according to another exemplary embodiment will be described with reference to FIG. 12 to FIG. 14.

As in the embodiment described above, a light-transmitting tube 20 having a pair of hooks 202 formed on an inner periphery thereof is prepared. As in the embodiment described above, an elongated linear slit 201 is formed over the entire length of the light-transmitting tube 20, except for a portion of the light-transmitting tube 20 near one end thereof, at the middle between the pair of hooks 202. In this embodiment, the slit 201 is formed by longitudinally cutting the light-transmitting tube 20 with a laser or a sharp cutter such as a knife.

Then, referring to FIG. 12, the width of slit 201 is widened by applying force to the light-transmitting tube 20 in a direction of an arrow, except for a portion near one end of the light-transmitting tube in which a slit is not formed. Next, as in the embodiment described above, the linear optical semiconductor module 40 is inserted in a sliding manner into the mounting gap formed by widening the slit 201.

Then, referring to FIG. 13, the portion L of the light-transmitting tube 20 in which the slit 201 is not formed is cut and removed from the light-transmitting tube 20. As a result, the slit 201 is formed over the entire length of the light-transmitting tube 20. After removing the portion of the light-transmitting tube 20, the optical semiconductor module 40 is further pushed into the mounting gap in the case where the optical semiconductor module 40 is not sufficiently inserted into the mounting gap. The method according to this embodiment has various advantages. Particularly, this method may provides process convenience obtained by widening one side of the slit 201 of the elongated light-transmitting tube 20, and a lighting apparatus, for example, like the lighting apparatus according to the embodiment shown in FIG. 1 to FIG. 5, by forming a plurality of slits in the light-transmitting tube 20 and mounting a plurality of optical semiconductor modules to the plurality of slits.

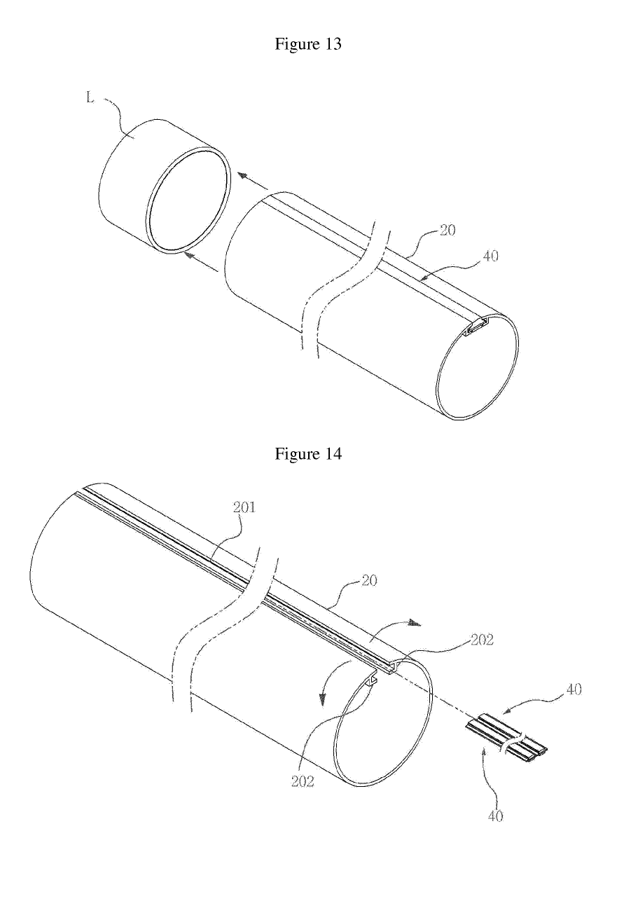

In the exemplary embodiments described above, a single optical semiconductor module 40 is illustrated as being inserted into a single mounting gap or a single slit 201 of the light-transmitting tube 20. However, it may be contemplated that two or more optical semiconductor modules 40 may be inserted together into a single mounting gap or a single slit 201 in an optical semiconductor-based tube type lighting apparatus according to another exemplary embodiment, as shown in FIG. 14.

Referring to FIG. 14, with adjacent side surfaces of the two optical semiconductor modules 40 coupled to each other, the two optical semiconductor modules 40 are inserted into a single slit 201 of a light-transmitting tube 20. At this time, protrusions on side surfaces of the two semiconductor modules 40, which are not adjacent each other, may be respectively inserted into a pair of hooks 202 of the light-transmitting tube 20 in a sliding manner. The structure wherein the adjacent side surfaces of the two optical semiconductor modules are coupled to each other may be modified in various ways, and thus a detailed description thereof will be omitted herein. Further, the two optical semiconductor modules 40 inserted into a single slit may be collinearly connected to each other or may be connected to each other to cross at a predetermined angle.

As such, according to embodiments of the invention, the optical semiconductor-based tube type lighting apparatus includes a first optical semiconductor module emitting light towards a lower front side of a light-transmitting tube, and second and third optical semiconductor modules emitting light towards an upper rear side of the light-transmitting tube. Thus, the optical semiconductor-based tube type lighting apparatus according to the exemplary embodiments does not suffer from a problem of conventional tube type or fluorescent lamp type LED lighting apparatuses in which the upper rear region of the light-transmitting tube is relatively dark.

According to the exemplary embodiment, in the optical semiconductor-based tube type lighting apparatus, some of the optical semiconductor modules are configured to have different color temperatures, so that the optical semiconductor-based tube type lighting apparatus may be used as an indirect lamp. As such, the optical semiconductor-based tube type lighting apparatus according to the exemplary embodiments may be suited not only to general indoor lighting, but also to outdoor lighting.

According to the exemplary embodiments, in the tube type optical semiconductor-based lighting apparatus, the bar-shaped optical semiconductor modules are directly mounted on the wall of the light-transmitting tube to increase the distance between the semiconductor optical devices and the light-transmitting tube, thereby increasing light distribution. Further, according to the exemplary embodiments, when mounting the bar-shaped optical semiconductor module directly on the wall of the light-transmitting tube such that the semiconductor module is partially exposed from the light-transmitting tube, the slit formed on the light-transmitting tube is widened to allow the optical semiconductor module to be easily inserted into the widened slit in a sliding manner, thereby significantly improving assembly properties of the optical semiconductor-based tube type lighting apparatus.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An optical semiconductor-based lighting apparatus comprising:
an elongated light-transmitting tube;
a linear slit formed on the light-transmitting tube in a longitudinal direction thereof; and
at least one bar-shaped optical semiconductor module secured to the light-transmitting tube, side surfaces of the bar-shaped optical semiconductor module being fitted into edges of the slit in a widened state and the side surfaces of the optical semiconductor module being subjected to elastic force from the light-transmitting tube in a direction of narrowing the slit,
the optical semiconductor module comprising a heat sink, a PCB attached to the heat sink, and an array of semiconductor optical devices arranged on the PCB, the heat sink being partially exposed from the light-transmitting tube through the slit.

2. The optical semiconductor-based lighting apparatus of claim 1, wherein the light-transmitting tube comprises a pair of hooks formed on an inner periphery thereof in the longitudinal direction of the light transmitting tube to face each other, the slit is formed at a middle between the pair of hooks in the longitudinal direction of the light transmitting tube, and right and left protrusions of the optical semiconductor module are respectively inserted into the pair of hooks in a sliding manner when the slit is widened by external force.

3. The optical semiconductor-based lighting apparatus of claim 2, wherein when the slit is widened by external force, a heat dissipation protrusion at a rear side of the heat sink is inserted into the slit in a sliding manner and exposed from the light-transmitting tube.

4. The optical semiconductor-based lighting apparatus of claim 2, wherein the heat sink is provided with right and left guide wings, and the right and left guide wings and right and left edges of the PCB are inserted into the corresponding hooks to form the right and left protrusions of the optical semiconductor module, respectively.

5. The optical semiconductor-based lighting apparatus of claim 1, wherein the PCB is a metal-based MCPCB or MPCB.

6. The optical semiconductor-based lighting apparatus of claim 1, wherein each of the optical semiconductor modules is disposed so as not to face another optical semiconductor module at an opposite side thereof in the light-transmitting tube.

7. The optical semiconductor-based lighting apparatus of any one of claims 1 to 6, wherein the light-transmitting tube has an undulating light spreading pattern formed on the inner periphery thereof.

8. A method of manufacturing a semiconductor-based tube type lighting apparatus, comprising:
preparing an elongated light-transmitting tube;
forming a linear slit on the light-transmitting tube in a longitudinal direction of the light-transmitting tube; and
assembling at least one optical semiconductor module to the light-transmitting tube by widening the slit and inserting the at least one optical semiconductor module into the widened slit in a sliding manner.

9. The method of claim 8, wherein the light-transmitting tube comprises a pair of hooks formed on an inner periphery of the light-transmitting tube to face each other in a longitudinal direction.

10. The method of claim 9, wherein the assembling at least one optical semiconductor module comprises inserting right and left protrusions formed at opposite sides of the optical semiconductor module into the respective hooks in a sliding manner, and inserting a rear protrusion of the optical semiconductor module into the widened slit in a sliding manner to be exposed from the light-transmitting tube.

11. The method of any one of claims 8 to 10, wherein the forming a linear slit comprises forming the slit over the entire length of the light-transmitting tube, and the assembling at least one optical semiconductor module comprises widening the slit over the entire length of the light-transmitting tube and inserting the optical semiconductor module into the slit.

12. The method of any one of claims 8 to 10, wherein the forming a linear slit comprises forming the slit on the light emitting tube except for a portion near one end of the light-transmitting tube, and the assembling at least one optical semiconductor module comprises widening the slit only in a partial length region of the light-transmitting tube and inserting the optical semiconductor module into the widened slit.

13. The method of claim 12, further comprising: removing the portion of the light-transmitting tube where the slit is not formed, after assembling the at least one optical semiconductor module.
